(19) United States
(12) Patent Application Publication
(10) Pub. No.: US 2014/0225136 A1
(43) Pub. Date: Aug. 14, 2014

(54) LIGHT EMITTING DIODE, DISPLAY DEVICE INCLUDING THE SAME, AND METHOD OF MANUFACTURING DISPLAY DEVICE

(71) Applicant: Samsung Display Co., Ltd., Yongin-city (KR)

(72) Inventors: Hoon Sik Kim, Seoul (KR); Young Min Kim, Yongin-si (KR); Hyuk-Hwan Kim, Hwaseong-si (KR); O Sung Seo, Seoul (KR); Hyoung Cheol Lee, Suwon-si (KR); Tae Kyung Yim, Seoul (KR)

(73) Assignee: Samsung Display Co., Ltd., Yongin-city (KR)

(21) Appl. No.: 14/063,862

(22) Filed: Oct. 25, 2013

(30) Foreign Application Priority Data
Feb. 12, 2013 (KR) 10-2013-0014966

(51) Int. Cl. H01L 33/50; H01L 33/00

(52) U.S. Cl. CPC H01L 33/502; H01L 33/0095
USPC 257/89; 257/98; 438/27

(57) ABSTRACT

A light emitting diode (LED), includes: a substrate; a first electrode connection line disposed on the substrate; a second electrode connection line disposed on the substrate; a first contact metal layer disposed on the first electrode connection line; a second contact metal layer disposed on the second electrode connection line; a light emitting unit disposed on the first contact metal layer and the second contact metal layer; a partition disposed on the substrate and about the light emitting unit; and an encapsulation layer covering the light emitting unit. The encapsulation layer includes a light conversion material.

### CROSS REFERENCE TO RELATED APPLICATION

This application claims priority from and the benefit of Korean Patent Application No. 10-2013-0014966, filed on Feb. 12, 2013, which is incorporated by reference for all purposes as if set forth herein.

### BACKGROUND

1. Field

Exemplary embodiments relate to a light emitting diode (LED), a display device including the LED, and a manufacturing method of a display device.

2. Discussion

A light emitting diode (LED) converts energy generated by recombining an electron and a hole of a bonded semiconductor into light. Light emitting diodes are typically used as or in a light, a display device, and a light source.

Conventionally, when an LED is used as a light-emitting device in a display device, combinations of various colors may be displayed. For example, the LED may include a red LED, a green LED, and a blue LED.

To form an LED as a light-emitting device of a display device, a lift-off method may be used. It is difficult, however, to form a LED including the red LED on a transparent wafer. Accordingly, it is difficult to simultaneously form a red LED along with a blue LED and/or a green LED, as the process is complicated.

The above information disclosed in this Background section is only for enhancement of understanding of the background of the invention, and, therefore, it may contain information that does not form the prior art that is already known to a person of ordinary skill in the art.

### SUMMARY

Exemplary embodiments provide a light emitting diode (LED) formed by a simple process, a display device including the LED, and a manufacturing method of the display device.

Additional aspects will be set forth in the detailed description which follows and, in part, will be apparent from the disclosure, or may be learned by practice of the invention.

According to exemplary embodiments, a light emitting diode (LED) includes: a substrate, a first electrode connection line disposed on the substrate; a second electrode connection line disposed on the substrate; a first contact metal layer disposed on the first electrode connection line; a second contact metal layer disposed on the second electrode connection line; a light emitting unit disposed on the first contact metal layer and the second contact metal layer, a partition disposed on the substrate and about the light emitting unit; and an encapsulation layer covering the light emitting unit. The encapsulation layer includes a light conversion material.

According to exemplary embodiments, a display device, includes: a substrate comprising pixel areas; a first electrode connection line disposed on the substrate; a second electrode connection line disposed on the substrate; first contact metal layers disposed on the first electrode connection line; second contact metal layers disposed on the second electrode connection line; light emitting units disposed on the first contact metal layers and the second contact metal layers; a partition disposed on the substrate and about at least one of the light emitting units; and an encapsulation layer covering at least one of the light emitting units. Each pixel area includes at least one of the light emitting units.

According to exemplary embodiments, a method of manufacturing a display device, includes: forming light emitting units on a wafer, forming a first electrode connection line on a substrate including pixel areas; forming a second electrode connection line on the substrate; and transferring at least one of the light emitting units to the substrate in association with at least one of the pixel areas.

According to exemplary embodiments, a display device including the light emitting diode may be formed by a relatively simple process using a lift-off method. In this manner, a red light emitting diode (LED) or a green light emitting diode (LED) may be realized using a light conversion material.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a cross-sectional view of a light emitting diode (LED), according to exemplary embodiments.

FIG. 2 is a plan view of a display device including a light emitting diode (LED), according to exemplary embodiments.

FIGS. 3, 4, 5, 6A, 6B, 6C, 7, 8, and 9 are respective views of a display device at various manufacturing stages, according to exemplary embodiments.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers and/or sections, these elements, components, regions, layers and/or sections should not be limited by these terms. These terms are used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper,” and/or the like, may be used herein for descriptive purposes, and thereby, to describe one element or feature's relationship to another element(s) or feature(s) as illustrated in the drawings. Spatially relative terms are intended to encompass different orientations of an apparatus in use or operation in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and as such, the spatially relative descriptors used herein interpreted accordingly.

The terminology used herein is for the purpose of describing particular embodiments and is not intended to be limiting. As used herein, the singular forms “a,” “an,” and “the” are intended to include the plural forms as well, unless the context clearly indicates otherwise. Moreover, the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

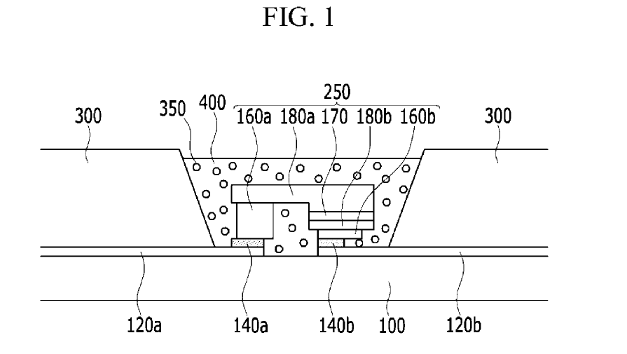

FIG. 1 is a cross-sectional view of a light emitting diode (LED), according to exemplary embodiments.

Referring to FIG. 1, a first electrode connection line 120a and second electrode connection line 120b may be positioned on a substrate 100. The first electrode connection line 120a and the second electrode connection line 120b may supply current to a light emitting unit 250, such as a light emitting diode (LED).

A first contact metal layer 140a and a second contact metal layer 140b may be positioned at ends of the first electrode connection line 120a and the second electrode connection line 120b. The first contact metal layer 140a and the second contact metal layer 140b may connect a light emitting unit 250 to the first electrode connection line 120a and the second electrode connection line 120b. In this manner, current may flow to the light emitting unit 250 through the first electrode connection line 120a and the second electrode connection line 120b. The flow of current to the light emitting unit 250 through the first electrode connection line 120a and the second electrode connection line 120b may create conductivity and adhesion. The first contact metal layer 140a and the second contact metal layer 140b may be formed of a mixture that may include any suitable material, such as, for example, indium, silver, gold, etc., any suitable cold-welded material, e.g., cold-welded silver or gold, or any suitable metal material, such as anisotropic conductive paste.

The light emitting unit 250 contacting the first contact metal layer 140a and the second contact metal layer 140b may be positioned on the substrate 100. The light emitting unit 250 may include a first conductive type semiconductor layer 180a, an active layer 170, a second conductive type semiconductor layer 180b, a first electrode 160a, and a second electrode 160b. It is noted that the first electrode 160a contacts the first contact metal layer 140a and the second electrode 160b contacts the second contact metal layer 140b.

The first electrode 160a may be positioned beneath the first conductive type semiconductor layer 180a, and the second electrode 160b may positioned beneath the second conductive type semiconductor layer 180b. Accordingly, the light emitting unit 250 according to exemplary embodiments may have an “overturned” structure.

A partition 300 enclosing (or otherwise surrounding) the light emitting unit 250 may be positioned on the substrate 100. The first electrode connection line 140a and the second electrode connection line 140b may be positioned between the substrate 100 and the partition 300. An encapsulation layer 400 may cover the light emitting unit 250 and may be formed between the partitions 300. The encapsulation layer 400 may protect the light emitting unit 250 from external moisture and dust, as well as other containments and/or environmental factors. Phosphors 350 may be distributed in the encapsulation layer 400. The phosphors 350 may be nano-phosphors or core-shell phosphors. The phosphors 350 may be a light converting material that converts light of a first wavelength into light of at least one second wavelength. The phosphors 350 may include Cadmium Selenide (CdSe)/Zinc Sulfide (ZnS).

The light emitting unit 250 may be a blue light emitting unit, and the phosphor 350 may convert the light generated from, for example, the blue light emitting unit into green and/or red light. It is contemplated, however, that light emitting unit 250 may be configured to generate light of any suitable wavelength and the phosphors 350 may be configured to convert such light into any suitable number of second wavelengths.

The first contact metal layer 140a and the second contact metal layer 140b may extend into the encapsulation layer 400.

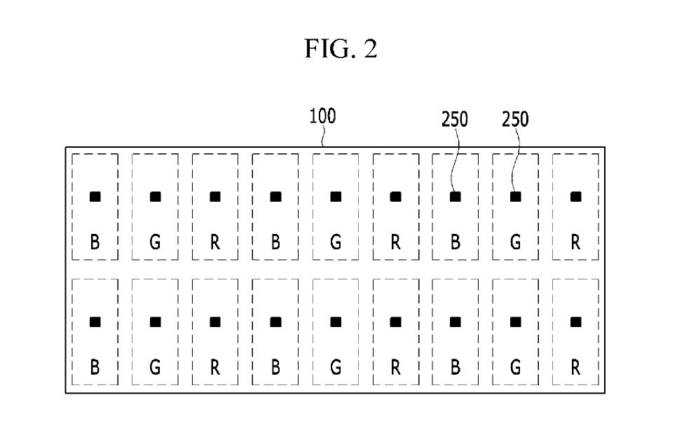

FIG. 2 is a top plan view of a display device including a light emitting diode (LED), according to exemplary embodiments.

Referring to FIG. 2, the substrate 100 may include a plurality of pixel areas R, G and B, and the pixel area may include, for example, a red pixel region (R), a green pixel region (G), and a blue pixel area (B). It is contemplated, however, that the pixel regions may be of any suitable color or may include one or more colors. Each pixel area may be arranged alternately in a horizontal direction, and pixel areas of the same color may be arranged in a vertical direction, however the arrangement of pixel areas may be in any suitable fashion.

On the substrate 100, the light emitting diode (LED), as shown in FIG. 1, may be formed corresponding to the pixel areas R, G, and B.

One light emitting unit 250 may be disposed in each pixel area, and although not shown in detail, as shown in FIG. 1, the first electrode connection line 120a and the second electrode connection line 120b may be connected to the light emitting unit 250 by the first contact metal layer 140a and the second contact metal layer 140b on the substrate 100. The light emitting unit 250 may be enclosed by the partition 300, and the encapsulation layer 400 covering the light emitting unit 250 may be formed while being filled between the partitions 300. In exemplary embodiments, the constitution of the light emitting unit 250 may be the same as described in FIG. 1, and, as such, a duplicative detailed description is omitted to avoid obscuring exemplary embodiments disclosed herein.

According to exemplary embodiments, the light emitting unit 250 may be the blue light emitting unit in all pixel areas R, G, and B. In this manner, the red pixel region (R) and the green pixel region (G) may include a color conversion material distributed in the encapsulation layer 400 covering the light emitting unit 250 to convert the blue light generated by the light emitting unit 250. The color conversion material may be the phosphor 350. The phosphor 350 may be the nano-phosphor or the core-shell phosphor. The color conversion material may not be disposed in the blue pixel area (B), and, as such, the encapsulation layer 400 may not include the color conversion material.

According to exemplary embodiments, the encapsulation layer 400 distributed with the color conversion material may not be disposed in the blue pixel area (B), such that the partition 300 may not be formed, and a coating layer (not shown) may be formed to entirely cover the substrate 100, the first electrode connection line 120a, the second electrode connection line 120b, and the light emitting unit 250. In this manner, in the red pixel region (R) and the green pixel region (G), the coating layer may cover the partition 300 and the encapsulation layer 400.

The first electrode connection line 120a and the second electrode connection line 120b may be connected by one line throughout all pixel areas R, G, and B; however, they may be separately formed for each pixel area and may be connected to an external power source (not shown).

The display device may be a passive display device or an active display device. In this manner, an active display device may include a switching element, such as a thin film transistor, and a driving element formed on the substrate 100.

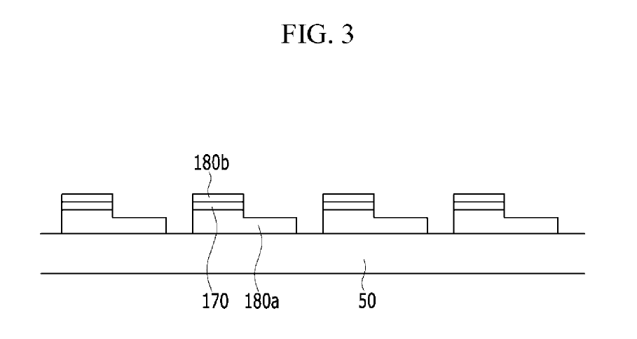

A method of manufacturing an exemplary display device will be described in more detail with reference to FIGS. 3-9.

FIGS. 3-9 are respective view of a display device at various manufacturing stages, according to exemplary embodiments.

Referring to FIG. 3, the first conductive type semiconductor layer 180a may be formed on a wafer 50. An active layer 170 may be formed on the first conductive type semiconductor layer 180a, and the second conductive type semiconductor layer 180b may be formed on the active layer 170. The wafer 50 may be formed of any suitable light transmitting material. For instance, the wafer 50 may be a sapphire wafer.

The first conductive type semiconductor layer 180a may be a “p” type semiconductor layer and may be formed of any suitable material, such as, for example, gallium nitride (GaN). The active layer 170 may be formed of at least one material selected from gallium nitride (GaN), indium gallium nitride (InGaN), aluminum gallium nitride (AlGaN), and indium aluminum gallium nitride (InAlGaN). It is contemplated; however, that any other suitable active layer material may be utilized. The second conductive type semiconductor layer 180b may be an “n” type semiconductor layer and may be formed of any suitable material, such as, for instance, zinc oxide (ZnO).

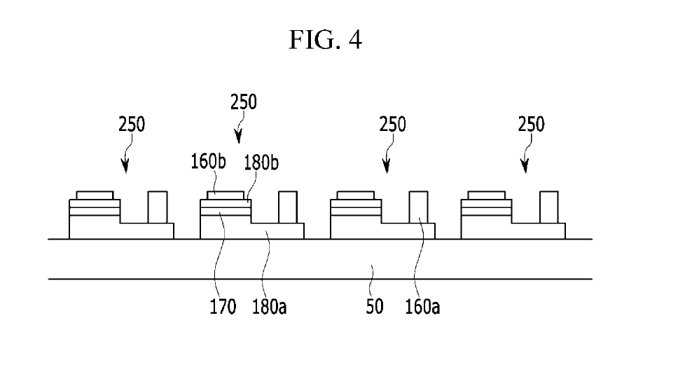

Referring to FIG. 4, the first electrode 160a and the second electrode 160b for electrical application may be formed. The first electrode 160a and the second electrode 160b may be formed of any suitable metal material having electrical conductivity. The electrode pattern may be formed by one or more photoresist processes and/or etching processes; however, any other suitable manufacturing technique may be utilized.

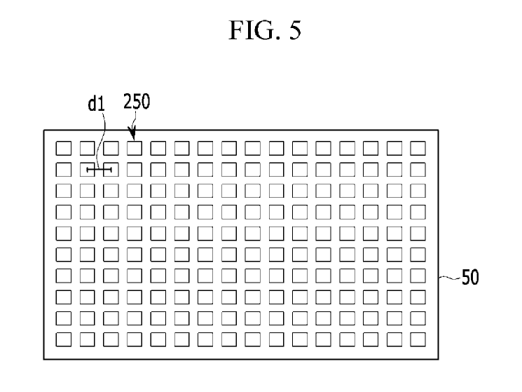

Referring to FIG. 5, a plurality of light emitting units 250 may be formed on the wafer 50. An interval between the plurality of light emitting units 250 may be a first interval dl.

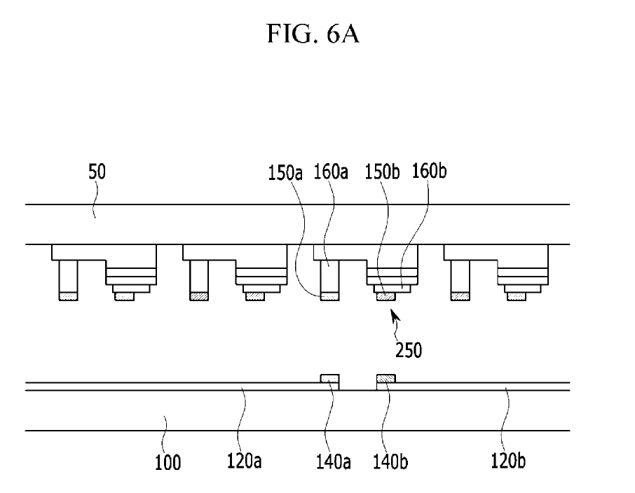

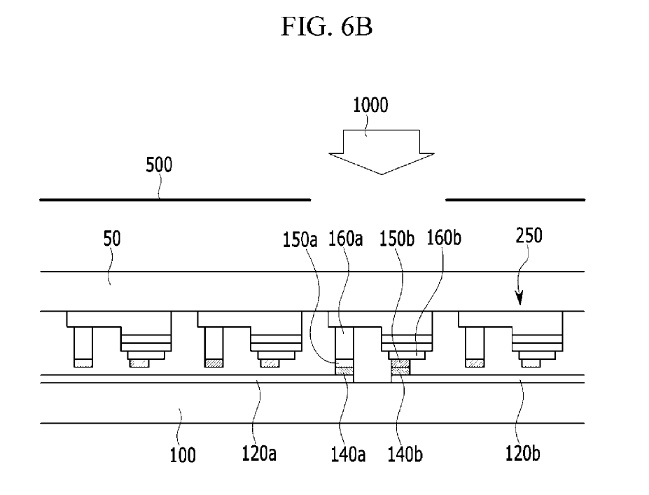

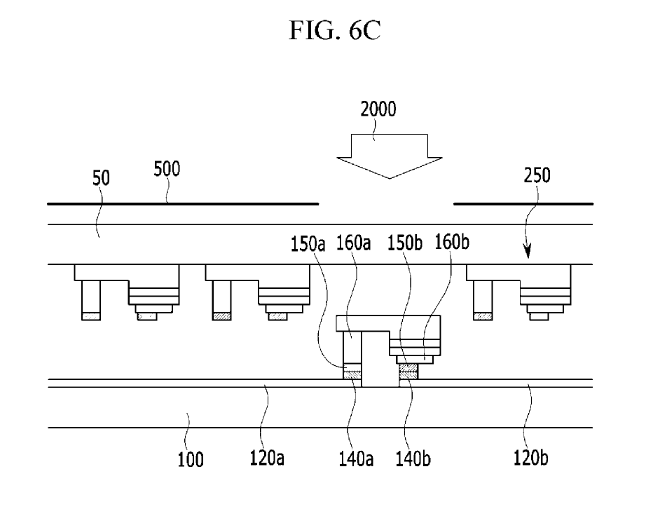

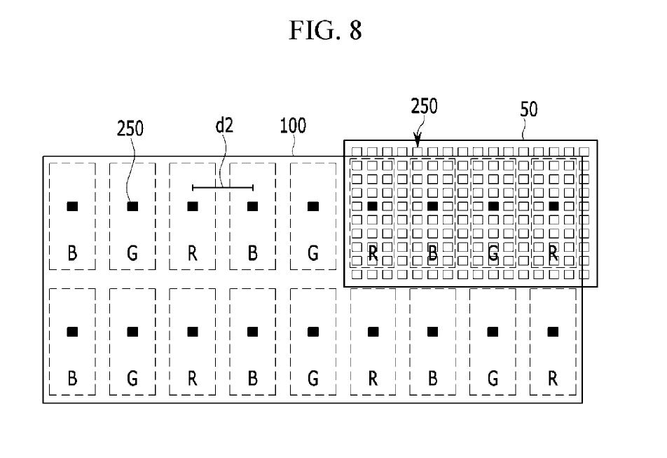

Referring to FIG. 6A, the first electrode connection line 120a and the second electrode connection line 120b may be formed on a substrate 100 using any suitable conductive material, such as, for example, a conductive metal material. The first electrode connection line 120a and the second electrode connection line 120b may be connected by one line through all pixel areas R, G, and B, which are shown in FIG. 8. However, the first electrode connection line 120a and the second electrode connection line 120b may be separately formed for each pixel area and may be connected to an external power source (not illustrated).

The first contact metal layer 140a and the second contact metal layer 140b may be formed at the ends of the first electrode connection line 120a and the second electrode connection line 120b. The wafer 50 formed with a plurality of light emitting units 250 disposed thereon may be turned to face the substrate 100. At least one of the plurality of light emitting units 250 may be arranged to correspond to the first contact metal layer 140a and the second contact metal layer 140b. The first electrode 160a and the second electrode 160b of the light emitting unit 250 may be arranged to correspond to the first contact metal layer 140a and the second contact metal layer 140b.

A first assistance contact metal layer 150a and a second assistance contact metal layer 150b may be formed on the first electrode 160a and the second electrode 160b to facilitate contact between the first electrode 160a and the first contact metal layer 140a, as well as facilitate contact between the second electrode 160b and the second contact metal layer 140b. The first assistance contact metal layer 150a and the second assistance contact metal layer 150b may be formed with the same material as the first contact metal layer 140a and the second contact metal layer 140b. It is contemplated, however, that any other suitable material may be utilized.

Referring to FIG. 6B, the wafer 50 may be moved close to the substrate 100, so that the first assistance contact metal layer 150a of the light emitting unit 250 can make contact with the first contact metal layer 140a, and the second assistance contact metal layer 150b can make contact with the second contact metal layer 140b. In this manner, a shadow mask 500 may be disposed on a surface of wafer 50 opposite to a surface on which the plurality of light emitting units 250 are formed. As such, infrared radiation 1000 may be irradiated through an open portion of the shadow mask. The infrared radiation 1000 may be passed through the wafer 50 and the light emitting unit 250 and may strike (or otherwise be incident on) the contact portion including the first assistance contact metal layer 150a and the first contact metal layer 140a. Accordingly, the first electrode 160a and the first electrode connection line 140a may be electrically and mechanically connected to each other, and the second electrode 160b and the second electrode connection line 140b may be electrically and mechanically connected to each other.

Referring to FIG. 6C, ultraviolet (UV) radiation 2000 may be irradiated through the open portion of the shadow mask 500. The irradiated ultraviolet (UV) radiation may disconnect a bond between the light emitting unit 250 and the wafer 50. As such, the light emitting unit 250 may be transferred from the wafer 50 to the corresponding substrate 100.

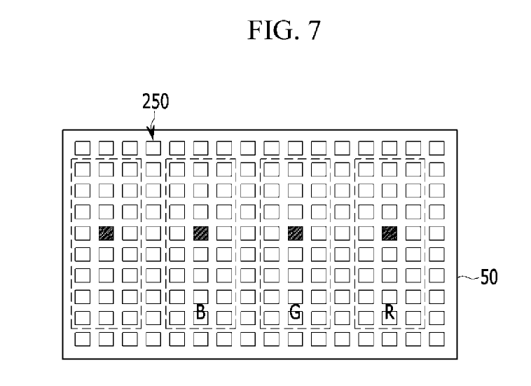

FIG. 7 is a plan view of a plurality of light emitting units 250 corresponding to pixel areas R, G, and B disposed on substrate 100 via wafer 50, according to exemplary embodiments.

Referring to FIG. 7, when transferring the light emitting units 250 from the wafer 50 to the substrate 100, a determined pattern may be formed. The light emitting units 250 transferred to the substrate 100 are indicated by a black colored portion in FIG. 7, and one light emitting unit 250 may be transferred to each pixel area. It is contemplated, however, that at least two light emitting units 250 may be simultaneously transferred to one of the pixel areas R, G, and B.

Referring to FIG. 8, a size of the wafer 50 may be smaller than a size of the substrate 100 such that it may be difficult to form a plurality of light emitting units 250 in all pixel areas R, G, and B of the substrate 100 through a single transferring process. As such, once one transferring process is finished, the transferring process may be repeated while moving the wafer 50 in a horizontal direction or a vertical direction. In this manner, the light emitting unit 250 formed on the substrate 100 may be arranged to correspond to each pixel area R, G, and B, and the interval between the light emitting units 250 disposed in adjacent pixel areas may be a second interval d2. The second interval d2 may be wider than the first interval d1, which is disposed between the light emitting units 250 formed on the wafer 50.

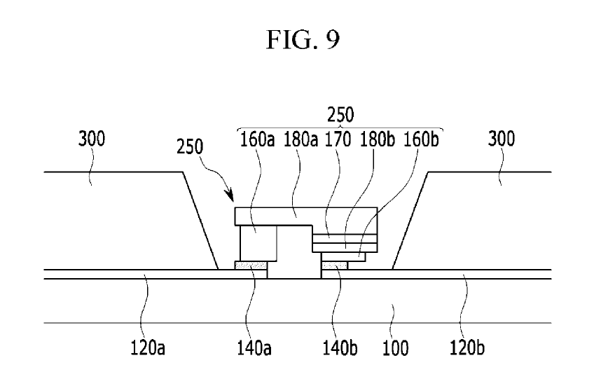

Referring to FIG. 9, a partition 300 may be formed on substrate 100. The partition 300 may enclose (or otherwise surround) the light emitting unit 250. If an encapsulation layer 400 covering the light emitting unit 250 is formed between the partitions 300, the structure, as shown in FIG. 1, may be formed. In the display device shown in FIG. 2, the light emitting unit 250 may be a blue light emitting unit in all pixel areas R, G, and B. As such, the encapsulation layer 400 including the color conversion material to convert blue light generated by the light emitting unit 250 may be formed in the red pixel region (R) and the green pixel region (G). The color conversion material may not be disposed in the blue pixel area (B), such that the encapsulation layer 400 without the color conversion material may be formed.

According to exemplary embodiments, the encapsulation layer 400 distributed with the color conversion material may not be disposed in the blue pixel area (B), such that the partition 300 may not be formed. As such, a coating layer (not shown) covering the substrate 100, the first electrode connection line 120a, the second electrode connection line 120b, and the light emitting unit 250 may be formed. To this end, in the red pixel region (R) and the green pixel region (G), the coating layer may cover the partition 300 and the encapsulation layer 400.

While certain exemplary embodiments and implementations have been described herein, other embodiments and modifications will be apparent from this description. Accordingly, the invention is not limited to such embodiments, but rather to the broader scope of the presented claims and various obvious modifications and equivalent arrangements.

What is claimed is:

1. A light emitting diode (LED), comprising:
a substrate;
a first electrode connection line disposed on the substrate;
a second electrode connection line disposed on the substrate;
a first contact metal layer disposed on the first electrode connection line;
a second contact metal layer disposed on the second electrode connection line;
a light emitting unit disposed on the first contact metal layer and the second contact metal layer;
a partition disposed on the substrate and about the light emitting unit; and
an encapsulation layer covering the light emitting unit,
wherein the encapsulation layer comprises a light conversion material.

2. The light emitting diode (LED) of claim 1, wherein:
the first electrode connection line and the second electrode connection line are disposed between the substrate and the partition.

3. The light emitting diode (LED) of claim 2, wherein:
the light emitting unit comprises:
a first conductive semiconductor layer,
a second conductive semiconductor layer,
an active layer disposed between the first conductive semiconductor layer and the second conductive semiconductor layer,
a first electrode, the first conductive semiconductor layer being disposed on the first electrode, and
a second electrode, the second conductive semiconductor layer being disposed on the second electrode;
the first electrode is connected to the first electrode connection line through the first contact metal layer; and
the second electrode is connected to the second electrode connection line through the second contact metal layer.

4. The light emitting diode (LED) of claim 3, wherein:
the first contact metal layer and the second contact metal layer are disposed in the encapsulation layer.

5. The light emitting diode (LED) of claim 4, wherein:
the light emitting unit is configured to emit light of a first wavelength; and
the encapsulation layer is configured to convert the light of the first wavelength into light of a second wavelength.

6. The light emitting diode (LED) of claim 5, wherein:
the light conversion material comprises a phosphor.

7. The light emitting diode (LED) of claim 6, wherein:
the phosphor comprises a core-shell phosphor.

8. A display device, comprising:
a substrate comprising pixel areas;
a first electrode connection line disposed on the substrate;
a second electrode connection line disposed on the substrate;
first contact metal layers disposed on the first electrode connection line;
second contact metal layers disposed on the second electrode connection line;
light emitting units disposed on the first contact metal layers and the second contact metal layers;
a partition disposed on the substrate and about at least one of the light emitting units; and
an encapsulation layer covering at least one of the light emitting units,
wherein each pixel area comprises at least one of the light emitting units.

9. The display device of claim 8, wherein:
the first electrode connection line and the second electrode connection line are disposed between the substrate and the partition.

10. The display device of claim 9, wherein:
each light emitting unit, comprises:
a first conductive semiconductor layer,
a second conductive semiconductor layer,
an active layer disposed between the first conductive semiconductor layer and the second conductive semiconductor layer,
a first electrode, the first conductive semiconductor layer being disposed on the first electrode, and
a second electrode, the second conductive semiconductor layer being disposed on the second electrode;
the first electrode is connected to the first electrode connection line through the first contact metal layer; and
the second electrode is connected to the second electrode connection line through the second contact metal layer.

11. The display device of claim 10, wherein:
the first contact metal layer and the second contact metal layer are disposed in the encapsulation layer.

12. The display device of claim 11, wherein:
the light emitting unit is configured to emit light of a first wavelength; and
the encapsulation layer is configured to convert the light of the first wavelength into light of a second wavelength.

13. The display device of claim 12, wherein:
the pixel areas comprise at least one red pixel area, at least one green pixel area, and at least one blue pixel area; and
the encapsulation layer comprises at least one light conversion material disposed in association with the red pixel area, the green pixel area, or the red pixel area and the green pixel area.

14. The display device of claim 13, wherein:
the light conversion material comprises a phosphor.

15. The display device of claim 14, wherein:
the phosphor comprises a core-shell phosphor.

16. A method of manufacturing a display device, the method comprising:
forming light emitting units on a wafer;
forming a first electrode connection line on a substrate comprising pixel areas;
forming a second electrode connection line on the substrate; and
transferring at least one of the light emitting units to the substrate in association with at least one of the pixel areas.

17. The method of claim 16, further comprising:
forming a first contact metal layer on the first electrode connection line;
forming a second contact metal layer on the second electrode connection line;
contacting at least one of the light emitting units with the first contact metal layer and the second contact metal layer;
irradiating a first type of radiation through a shadow mask disposed on a surface of the wafer opposite to a surface on which the at least one light emitting unit is disposed; and
disconnecting the at least one light emitting unit from the wafer to be formed on the substrate.

18. The method of claim 17, further comprising:
forming, on the substrate, a partition about the at least one light emitting unit; and
forming an encapsulation layer to cover the light emitting unit, the encapsulation layer comprising a light conversion material.

19. The method of claim 18, wherein:
the first electrode connection line and the second electrode connection line are formed between the substrate and the partition.

20. The method of claim 18, wherein:
the light emitting unit comprises:
a first conductive semiconductor layer,
a second conductive semiconductor layer,
an active layer disposed between the first conductive semiconductor layer and the second conductive semiconductor layer,
a first electrode, the first conductive semiconductor layer being disposed on the first electrode, and
a second electrode, the second conductive semiconductor layer being disposed on the second electrode;
the first electrode is connected to the first electrode connection line through the first contact metal layer; and
the second electrode is connected to the second electrode connection line through the second contact metal layer.

21. The method of claim 20, wherein:
the encapsulation layer is formed to encapsulate at least respective portions of the first contact metal layer and the second contact metal layer.

22. The method of claim 17, further comprising:
irradiating a second type of radiation through the shadow mask or applying pressure to corresponding contact portions of the first contact metal layer and the second contact metal layer that respectively contact the light emitting unit before irradiating the first type of radiation through the shadow mask.

23. The method of claim 17, wherein:
adjacent light emitting units formed on the wafer are formed in association with a first interval;
adjacent light emitting units formed on the substrate are formed in association with a second interval; and
the second interval is greater than the first interval.

24. The method of claim 16, further comprising:
displacing the wafer over the substrate; and
transferring at least one more of the light emitting units to the substrate in association with at least one other pixel area.

25. The method of claim 16, wherein:
the wafer comprises a transparent material.

26. The light emitting diode of claim 5, wherein:
the first wavelength corresponds to blue light; and
the second wavelength corresponds to green light or red light.

27. The display device of claim 12, wherein:
the first wavelength corresponds to blue light; and
the second wavelength corresponds to green light or red light.

28. The method of claim 22, wherein the first type of radiation is ultraviolet radiation and the second type of radiation is infrared radiation.
